(19) United States
(12) Patent Application Publication
(10) Pub. No.: US 2025/0031451 A1
(43) Pub. Date: Jan. 23, 2025

(54) DISPLAY DEVICE AND PRODUCTION METHOD FOR DISPLAY DEVICE

(71) Applicant: Sharp Display Technology Corporation, Kameyama City, Mie (JP)

(72) Inventor: Masatomo HONJO, Kameyama City, Mie (JP)

(21) Appl. No.: 18/715,544

(22) PCT Filed: Feb. 2, 2022
(86) PCT No.: PCT/JP2022/004094

§ 371 Date: May 31, 2024

(51) Int. Cl. H01L 27/12

(52) U.S. Cl. CPC H01L 27/1225; H01L 27/127

(57) ABSTRACT

A display device includes an insulating layer located in a gap between a first electrode and a second electrode and including an application-type insulating material, and an oxide semiconductor layer, at least a portion of which functions as a channel of a first transistor. The oxide semiconductor layer is in contact with the upper surface of the insulating layer.

### TECHNICAL FIELD

The present invention relates to a display device and a manufacturing method for the display device.

### BACKGROUND ART

PTL 1 discloses a top-gate transistor having a configuration in which a source electrode and a drain electrode are formed on a base insulating film including silicon oxynitride, and an oxide semiconductor is formed so as to fill a gap between the electrodes.

### CITATION LIST

### Patent Literature

PTL 1: JP 2013-058738 A (published on Mar. 28, 2013)
PTL 2: JP 2013-77815 A (published on Apr. 25, 2013)

### SUMMARY OF INVENTION

### Technical Problem

In such a conventional configuration as disclosed in PTL 1, there is a problem in that transistor characteristics cannot be improved.

### Solution to Problem

A display device according to an aspect of the disclosure includes a substrate and a first transistor located above the substrate. The display device includes a first electrode and a second electrode located above the substrate and spaced apart from each other in a direction orthogonal to a normal direction of the substrate, an insulating layer located in a gap between the first electrode and the second electrode and including an application-type insulating material, and an oxide semiconductor layer, at least a portion of the oxide semiconductor layer being configured to function as a channel of the first transistor, and the oxide semiconductor layer being in contact with an upper surface of the insulating layer.

### Advantageous Effects of Invention

According to an aspect of the disclosure, transistor characteristics can be improved as compared with prior art.

### BRIEF DESCRIPTION OF DRAWINGS

FIG. 1 is a schematic cross-sectional view illustrating a configuration example of a display device according to the disclosure.

FIG. 2 is a schematic cross-sectional view illustrating a configuration example of a first transistor according to the disclosure illustrated in FIG. 1.

FIG. 3 is a schematic cross-sectional view illustrating a configuration example of a display device according to Comparative Example.

FIG. 4 is a schematic cross-sectional view illustrating a configuration of a first transistor of Comparative Example illustrated in FIG. 3.

FIG. 5 is a schematic cross-sectional view illustrating a step of patterning an oxide semiconductor layer of Comparative Example illustrated in FIG. 3.

FIG. 6 is a diagram illustrating a difference in voltage-current characteristics of a second semiconductor, depending on the presence and absence of patterning of a third metal layer.

FIG. 7 is a schematic cross-sectional view illustrating an example of a step of forming a thin film transistor layer according to the disclosure.

FIG. 8 is a schematic plan view illustrating the example of the step of forming the thin film transistor layer according to the disclosure.

FIG. 9 is a schematic cross-sectional view illustrating the example of the step of forming the thin film transistor layer according to the disclosure.

FIG. 10 is a schematic plan view illustrating the example of the step of forming the thin film transistor layer according to the disclosure.

FIG. 11 is a schematic cross-sectional view illustrating the example of the step of forming the thin film transistor layer according to the disclosure.

FIG. 12 is a schematic plan view illustrating the example of the step of forming the thin film transistor layer according to the disclosure.

FIG. 13 is a schematic cross-sectional view illustrating the example of the step of forming the thin film transistor layer according to the disclosure.

FIG. 14 is a schematic plan view illustrating the example of the step of forming the thin film transistor layer according to the disclosure.

FIG. 15 is a schematic cross-sectional view illustrating the example of the step of forming the thin film transistor layer according to the disclosure.

FIG. 16 is a schematic plan view illustrating the example of the step of forming the thin film transistor layer according to the disclosure.

FIG. 17 is a schematic cross-sectional view illustrating a configuration example of the first transistor according to an embodiment of the disclosure.

FIG. 18 is a schematic cross-sectional view illustrating a configuration example of the first transistor according to an embodiment of the disclosure.

FIG. 19 is a schematic cross-sectional view illustrating an example of a step of forming the first transistor illustrated in FIG. 18.

FIG. 20 is a schematic cross-sectional view illustrating an example of the step of forming the first transistor illustrated in FIG. 18.

### DESCRIPTION OF EMBODIMENTS

In the disclosure, “same layer” means a layer formed through the same process (film formation step), “lower layer” means a layer formed through a process before that of a comparison layer, and “upper layer” means a layer formed through a process after that of the comparison layer.

In the following description, when a description “Y is on X”, “Y is above X”, or “Y is on the upper side of X” is used, X and Y may be in direct contact with each other, or X and Y need not necessarily be in direct contact with each other.

### First Embodiment

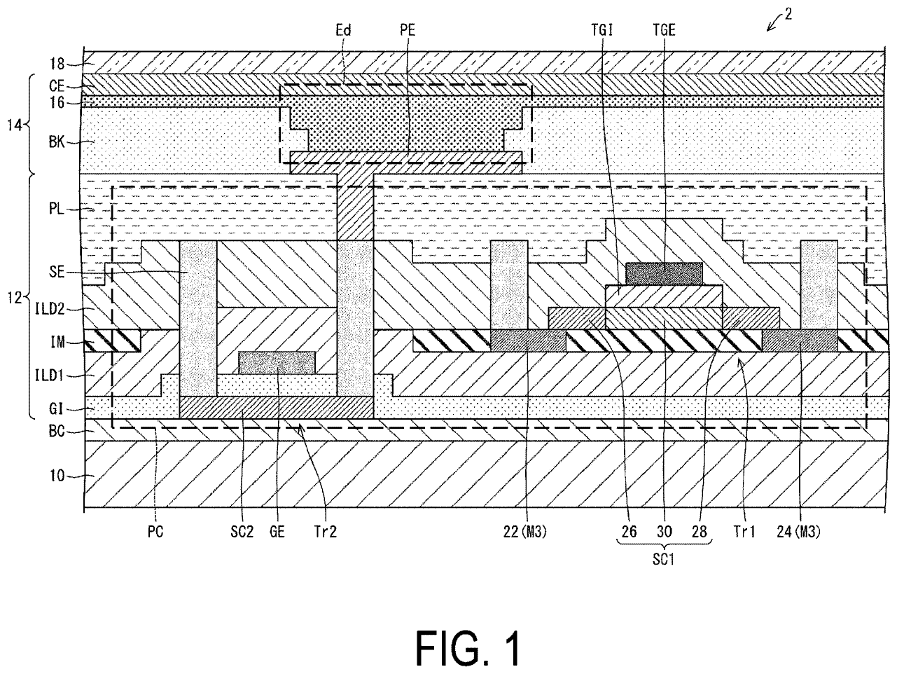

Configuration of Display Device FIG. 1 is a schematic cross-sectional view illustrating a configuration example of a display device 2 according to the disclosure. As illustrated in FIG. 1, the display device 2 according to the disclosure includes a resin substrate 10, a base coat layer BC layered above the resin substrate 10, a thin film transistor layer 12 layered above the base coat layer BC, a light-emitting element layer 14 layered above the thin film transistor layer 12, and a sealing layer 18 layered above the light-emitting element layer 14.

The display device 2 includes a plurality of pixel circuits PC and a light-emitting element Ed connected to each of the pixel circuits PC.

The resin substrate 10 may be a rigid substrate or a flexible substrate. The resin substrate 10 is a substrate formed of, for example, a resin such as polyimide.

The thin film transistor layer 12 according to the present embodiment includes a silicon-based semiconductor layer SC2, a gate insulating film GI, a gate electrode GE (second gate electrode), a first interlayer insulating film ILD1 (inorganic insulating film), a metal layer M3, an insulating layer IM, an oxide semiconductor layer SC1, a gate insulating film TGI, a gate electrode TGE (first gate electrode), a second interlayer insulating film ILD2, a metal layer SE, and an organic flattening film PL in this order from the lower layer toward the upper layer.

The thin film transistor layer 12 includes a first transistor Tr1 and a second transistor Tr2. The first transistor Tr1 and the second transistor Tr2 are included in the pixel circuit PC.

The first transistor Tr1 will be described below.

The second transistor Tr2 includes the silicon-based semiconductor layer SC2, the gate insulating film GI layered above the silicon-based semiconductor layer SC2, and the gate electrode GE layered above the gate insulating film GI.

The silicon-based semiconductor layer SC2 may include any of single crystal silicon, polycrystalline silicon, and amorphous silicon. The oxide semiconductor layer SC1 includes an oxide semiconductor. Examples of the oxide semiconductor include indium gallium zinc oxide (InGaZnO).

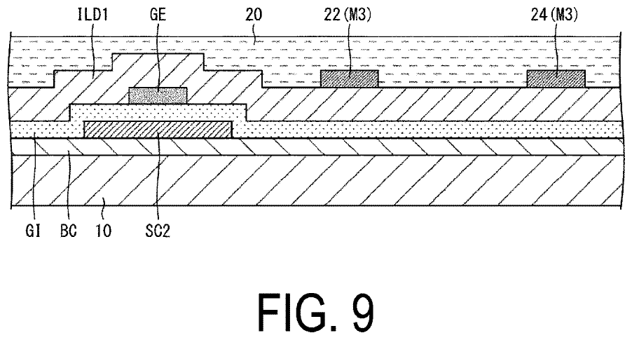

The insulating layer IM is formed by applying and solidifying a liquid 20 (see FIG. 9) including an application-type insulating material. The insulating layer IM includes the application-type insulating material. The insulating layer IM may include, for example, at least one of a spin on glass (SOG) material, an oxide including an alkaline earth metal, or an oxide including lanthanoid. The insulating layer IM will be described below.

The light-emitting element layer 14 includes a pixel electrode PE, a bank BK layered above the pixel electrode PE, an active layer 16 layered above the bank BK, and a common electrode CE layered above the active layer 16.

The active layer 16 includes at least a light-emitting layer. Here, examples of the type of display device 2 include an OLED display device in which the light-emitting layer is an organic light-emitting layer, and a QLED display device in which the light-emitting layer is a quantum dot light-emitting layer. The active layer 16 may include one or more of a hole injection layer, a hole transport layer, and an electron transport layer, and an electron injection layer.

The display device 2 according to the disclosure is not limited to the configuration described above. For example, the display device 2 may include a glass substrate instead of the resin substrate 10. For example, the display device 2 may be a liquid crystal display device that includes an active matrix substrate including a substrate and the thin film transistor layer 12. For example, the display device 2 may be a rigid display device or a flexible display device.

### Configuration of First Transistor

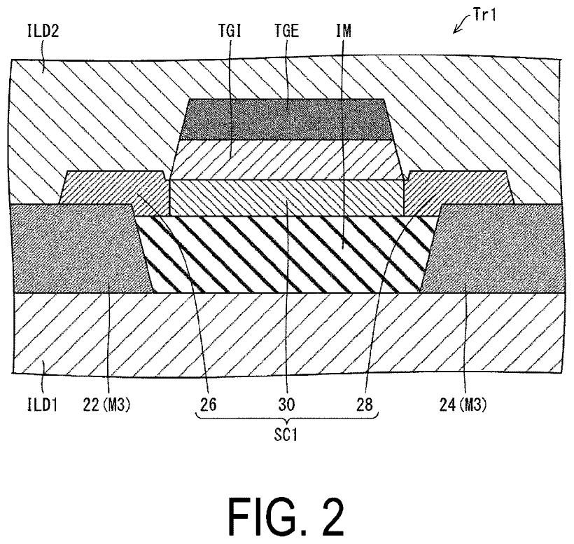

FIG. 2 is a schematic cross-sectional view illustrating a configuration example of the first transistor Tr1 according to the disclosure illustrated in FIG. 1. As illustrated in FIG. 2, the first transistor Tr1 is a thin film transistor (TFT) and includes (1) a first electrode 22 and a second electrode 24 spaced apart from each other in a direction orthogonal to the normal direction of the upper surface of the resin substrate 10, (2) the oxide semiconductor layer SC1 in contact with the upper surface of the insulating layer IM, the first electrode 22, and the second electrode 24, (3) the gate insulating film TGI layered above the oxide semiconductor layer SC1, and (4) the gate electrode TGE (first gate electrode) layered above the gate insulating film TGI. The first electrode 22 and the second electrode 24 are formed in the same layer and included in the metal layer M3. One of the first electrode 22 and the second electrode 24 is a source electrode, and the other thereof is a drain electrode.

The oxide semiconductor layer SC1 includes at least a channel portion 30 and can further include a first low-resistance portion 26 and a second low-resistance portion 28.

The channel portion 30 functions as a channel of the first transistor Tl. The channel portion 30 is in contact with the upper surface of the insulating layer IM and overlaps the gate electrode TGE in a plan view.

The first low-resistance portion 26 is located on the first electrode 22 side with respect to the channel portion 30, and has an electrical resistance value less than that of the channel portion 30. The first low-resistance portion 26 is in contact with the upper surface of the first electrode 22. The first low-resistance portion 26 may also be in contact with the side surface of the first electrode 22.

The second low-resistance portion 28 is located on the second electrode 24 side with respect to the channel portion 30, and has an electrical resistance value less than that of the channel portion 30. The second low-resistance portion 28 is in contact with at least one of the upper surface or the side surface of the second electrode 24. The second low-resistance portion 28 may also be in contact with the side surface of the second electrode 24.

### Insulating Layer IM

The insulating layer IM is formed at least in a gap between the first electrode 22 and the second electrode 24 of the first transistor Tl. The insulating layer IM is in contact with both the side surfaces of the first electrode 22 and the second electrode 24. In addition, the insulating layer IM may be formed so as to surround each of the first electrode 22 and the second electrode 24 of the first transistor Tr1 in a plan view.

The upper surface of the insulating layer IM is substantially flat. The distance from the upper surface of the insulating layer IM to the upper surface of the resin substrate 10 is less than the distance from the upper surfaces of the first electrode 22 and the second electrode 24 of the first transistor Tr1 to the upper surface of the resin substrate 10. The insulating layer IM, the first electrode 22, and the second electrode 24 are provided on the first interlayer insulating film ILD1. Therefore, the upper surface of the insulating layer IM is located between the upper surface of the first electrode 22 and the upper surface of the first interlayer insulating film ILD1, or between the upper surface of the second electrode 24 and the upper surface of the first interlayer insulating film ILD1.

### Comparative Example

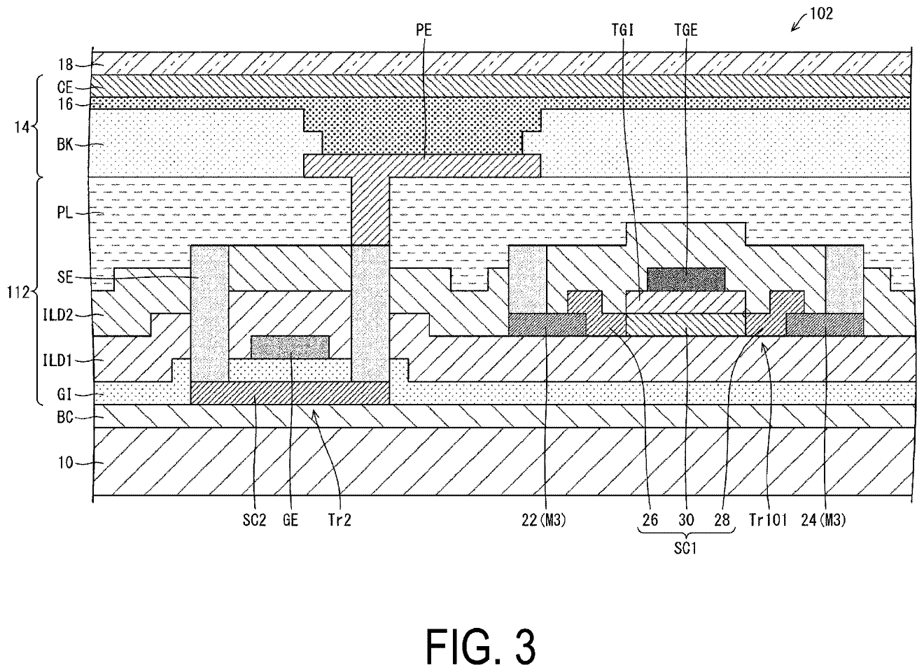

FIG. 3 is a schematic cross-sectional view illustrating a configuration example of a display device 102 according to Comparative Example. As illustrated in FIG. 3, the display device 102 according to Comparative Example has the same configuration as that of the display device 2 according to the disclosure illustrated in FIG. 1, except that the insulating layer IM is not provided between the first interlayer insulating film ILD1 and the oxide semiconductor layer SC1 of the thin film transistor layer 112.

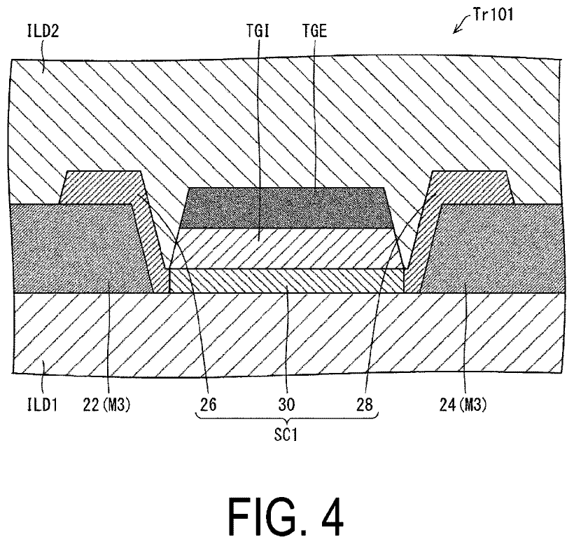

FIG. 4 is a schematic cross-sectional view illustrating a configuration of a first transistor Tr101 illustrated in FIG. 3. As illustrated in FIG. 4, in the first transistor Tr101 according to Comparative Example, the oxide semiconductor layer SC1 is in contact with the side surfaces of the first electrode 22 and the second electrode 24, and the upper surface of the first interlayer insulating film ILD1 between the first electrode 22 and the second electrode 24. The oxide semiconductor layer SC1 in contact with the side surfaces of the first electrode 22 and the second electrode 24 tends to be formed thinner than the oxide semiconductor layer SC1 in contact with the upper surface of the first interlayer insulating film ILD1.

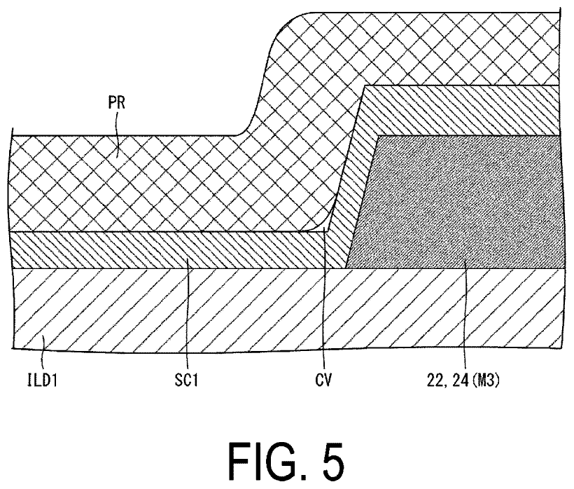

Comparison Between Configuration According to Disclosure and Configuration According to Comparative Example FIG. 5 is a schematic cross-sectional view illustrating a step of patterning the oxide semiconductor layer SC1 illustrated in FIG. 3. As illustrated in FIG. 5, when patterning the oxide semiconductor layer SC1 according to Comparative Example, a photoresist layer PR is formed on the oxide semiconductor layer SC1. At this time, a cavity CV may be generated between the oxide semiconductor layer SC1 and the photoresist layer PR at a position corresponding to a corner between the upper surface of the first interlayer insulating film ILD1 and an inclined side surface of the source electrode or the drain electrode. Then, an etching solution for etching the oxide semiconductor layer SC1 is caused to soak into the cavity CB. Thus, the oxide semiconductor layer SC1 is likely to be disconnected (so-called “step disconnection”) due to a step between the first interlayer insulating film ILD1 and the source electrode or the drain electrode.

In addition, the upper surface of the first interlayer insulating film ILD1 may have deteriorated when patterning the metal layer M3, or a residue of the metal layer M3 may remain on the upper surface of the first interlayer insulating film ILD1.

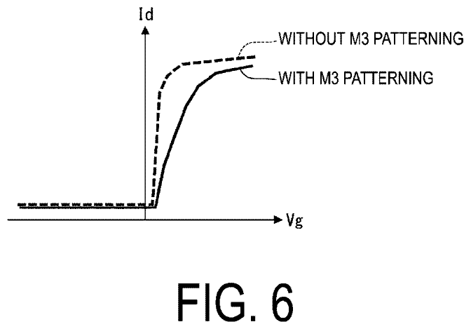

FIG. 6 is a semi-logarithmic graph showing current-voltage characteristics of the first transistor Tr101 in (1) a case in which the first transistor Tr101 is formed by patterning the metal layer M3 (with M3 patterning) and (2) a case in which the oxide semiconductor layer SC1 is patterned without forming the metal layer M3 and the oxide semiconductor layer SC1 is connected to the source electrode or the drain electrode via a top contact (without M3 patterning). The vertical axis of FIG. 6 represents the logarithm.

As illustrated in FIG. 6, it can be understood that the rising characteristics of the first transistor Tr101 deteriorate (the S value increases) when the M3 patterning is performed. This deterioration is considered to be caused by the deterioration of the upper surface of the first interlayer insulating film ILD1 and the residue of the metal layer M3.

As illustrated in FIG. 2, in the first transistor Tr1 according to the disclosure, the gap between the first electrode 22 and the second electrode 24 is filled with the insulating layer IM. The step between the upper surface of the insulating layer IM and the upper surface of the first electrode 22 or the second electrode 24 is smaller than the step between the upper surface of the first interlayer insulating film ILD1 and the upper surface of the first electrode 22 or the second electrode 24. Thus, as compared with the configuration of Comparative Example illustrated in FIG. 4, the oxide semiconductor layer SC1 in the configuration according to the disclosure illustrated in FIG. 2 is less likely to be subjected to the step disconnection. Further, since the oxide semiconductor layer SC1 is not in contact with the upper surface of the first interlayer insulating film ILD1, the deterioration of the upper surface of the first interlayer insulating film ILD1 and the residue of the metal layer M3 do not affect the oxide semiconductor layer SC1, and the rising characteristics of the first transistor Tr1 do not deteriorate.

Therefore, when the first transistor Tr1 according to the disclosure is compared with the first transistor Tr101 according to Comparative Example, the first transistor Tr1 according to the disclosure has higher transistor characteristics.

### Manufacturing Method

A manufacturing method for the display device 2 according to the disclosure includes steps of forming, in layers above the resin substrate 10, the base coat layer BC, the thin film transistor layer 12, the light-emitting element layer 14, and the sealing layer 18 in this order.

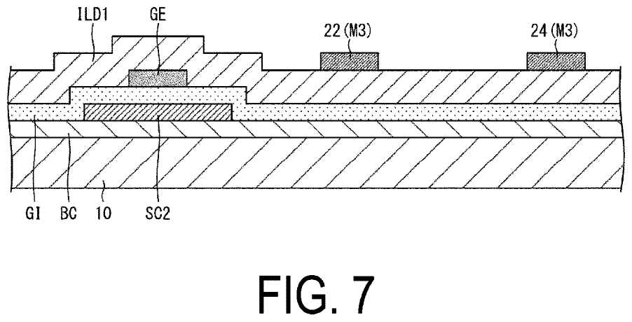

FIGS. 7, 9, 11, 13, and 15 are each a schematic cross-sectional view illustrating an example of a step of forming the thin film transistor layer 12 according to the disclosure.

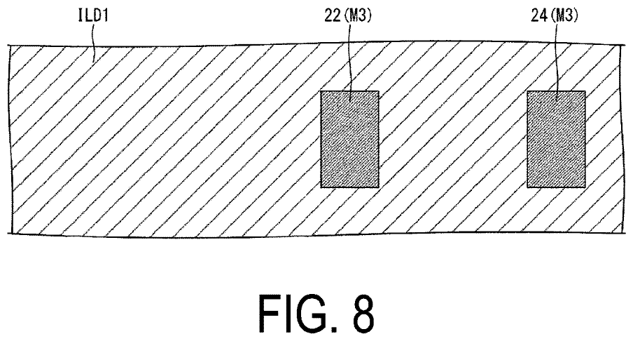

FIGS. 8, 10, 12, 14, and 16 are each a schematic plan view illustrating the example of the step of forming the thin film transistor layer 12 according to the disclosure.

As illustrated in FIGS. 7 and 8, first, the silicon-based semiconductor layer SC2, the gate insulating film GI, the gate electrode GE, the first interlayer insulating film ILD1, and the metal layer M3 are formed in this order on the base coat layer BC, and are appropriately patterned.

In the formation and patterning of the metal layer M3, the first electrode 22 and the second electrode 24 are formed so as to be spaced apart from each other in the direction orthogonal to the normal direction of the upper surface of the resin substrate 10.

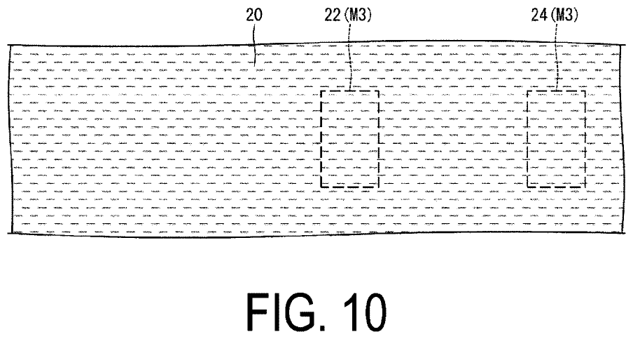

Subsequently, as illustrated in FIGS. 9 and 10, the liquid 20 including the application-type insulating material is applied so as to entirely cover the first interlayer insulating film ILD1 and the metal layer M3, thereby forming a coating film. Here, the liquid 20 is applied to the gap between the first electrode 22 and the second electrode 24.

It is sufficient that the liquid 20 including the application-type insulating material is an insulator when solidified (i.e., when it becomes the insulating layer IM), and the liquid 20 itself may be a conductor or an insulator. The liquid 20 including the application-type insulating material may be any liquid, such as a liquid in which a powder of an insulating material is dispersed in a solvent. The application method may be any method such as a spin coating method, a bar coating method, or a spraying method.

Subsequently, the coating film of the liquid 20 is baked so as to form the insulating layer IM. The insulating layer IM is formed on the first electrode 22 and the second electrode 24, in the gap therebetween, and around the first electrode 22 and the second electrode 24. Here, the thickness of a portion of the insulating layer IM formed on the first electrode 22 and the second electrode 24 is thinner than the thickness of a portion of the insulating layer IM formed in the gap therebetween.

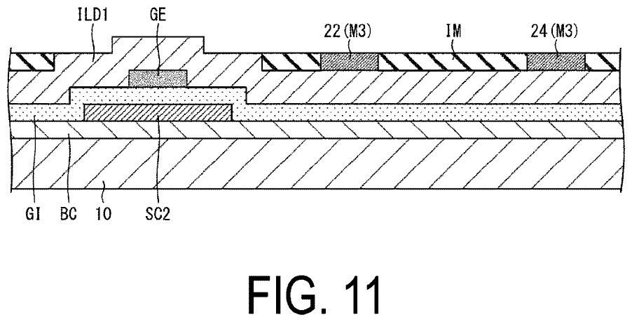

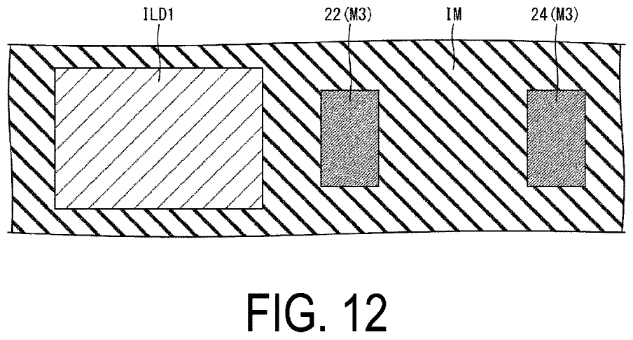

Subsequently, as illustrated in FIGS. 11 and 12, the insulating layer IM is etched so that the upper surfaces of both the first electrode 22 and the second electrode 24 are exposed from the insulating layer IM and the insulating layer IM remains at least in the gap between the first electrode 22 and the second electrode 24. In the present embodiment, the insulating layer IM is etched until a portion of the side surface of the first electrode 22 and a portion of the side surface of the second electrode 24 are exposed. As a result, the distance from the upper surface of the insulating layer IM to the upper surface of the resin substrate 10 becomes less than the distance from the upper surface of the first electrode 22 and the upper surface of the second electrode 24 to the upper surface of the resin substrate 10.

The etching method may be dry etching or wet etching. Here, when the first interlayer insulating film ILD1 is etched, the thickness, material, and etching conditions of the first interlayer insulating film ILD1 are set so that a gate electrode of the second transistors Tr2 remains covered with the first interlayer insulating film ILD1 even after the etching.

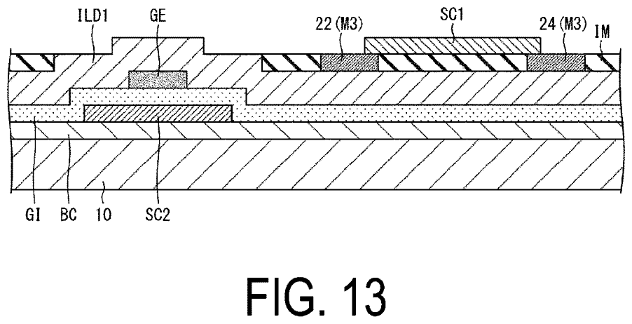

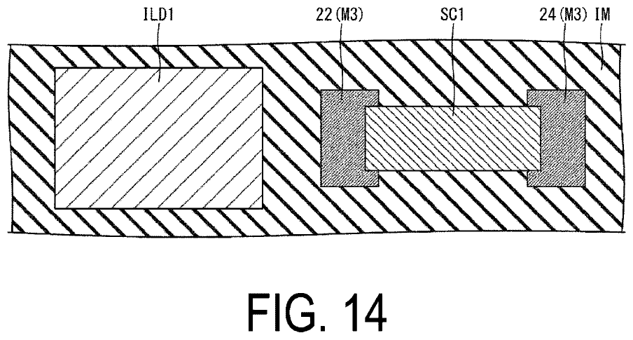

Subsequently, as illustrated in FIGS. 13 and 14, the oxide semiconductor layer SC1 is formed and patterned on the metal layer M3 and the insulating layer IM.

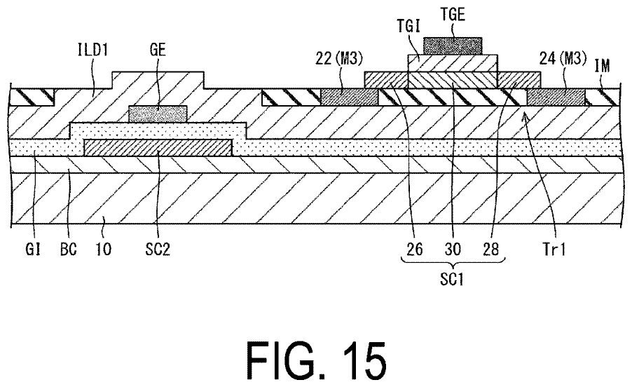

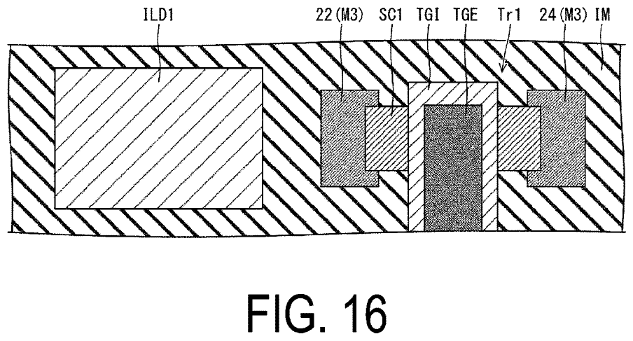

Subsequently, as illustrated in FIGS. 15 and 16, the gate insulating film TGI and the gate electrode TGE are formed on the oxide semiconductor layer SC1 in this order. In addition, a treatment for doping or reducing the oxide semiconductor layer SC1 may be performed. As a result of this treatment, a region including a portion, of the oxide semiconductor layer SC1, provided below the gate electrode TGE and overlapping the gate electrode TGE, remains as the channel portion 30, and the other region is reduced in resistance to form the first low-resistance portion 26 and the second low-resistance portion 28.

Subsequently, the second interlayer insulating film ILD2 is formed, contact holes are appropriately formed, and the metal layer SE and the organic flattening film PL are formed. As a result, the thin film transistor layer 12 is formed.

The manufacturing method for the display device 2 according to the disclosure is not limited to this example. For example, when the resin substrate 10 is flexible, a layered body including the thin film transistor layer 12 may be formed on a rigid substrate different from the resin substrate 10, and the layered body may be peeled off from the rigid substrate and attached to the resin substrate 10.

### Second Embodiment

Another embodiment of the present invention will be described below. Further, members having the same functions as those of the members described in the above-described embodiments will be denoted by the same reference numerals and signs, and the description thereof will not be repeated for the sake of convenience of description.

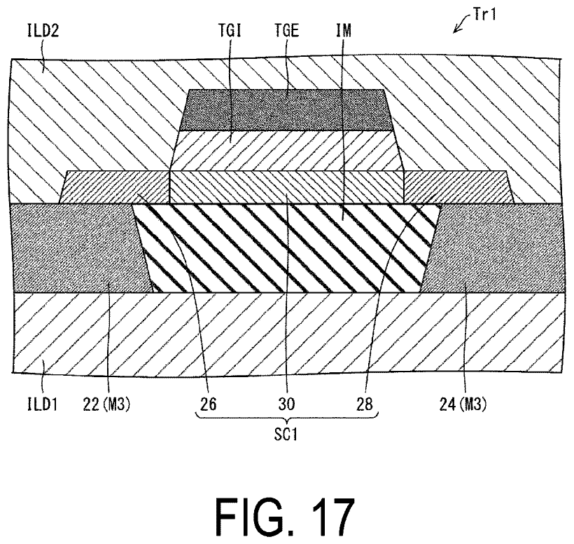

FIG. 17 is a schematic cross-sectional view illustrating a configuration example of the first transistor Tr1 according to the present embodiment. As illustrated in FIG. 17, the display device 2 according to the present embodiment is the same as the display device 2 according to the first embodiment described above, except that the distance from the upper surface of the insulating layer IM to the upper surface of the resin substrate 10 is identical to the distance from the upper surfaces of both the first electrode 22 and the drain electrode of the first transistors Tr1 to the upper surface of the resin substrate 10.

The insulating layer IM as described above can be realized by adjusting etching conditions when etching the insulating layer IM.

### Third Embodiment

Another embodiment of the present invention will be described below. Further, members having the same functions as those of the members described in the above-described embodiments will be denoted by the same reference numerals and signs, and the description thereof will not be repeated for the sake of convenience of description.

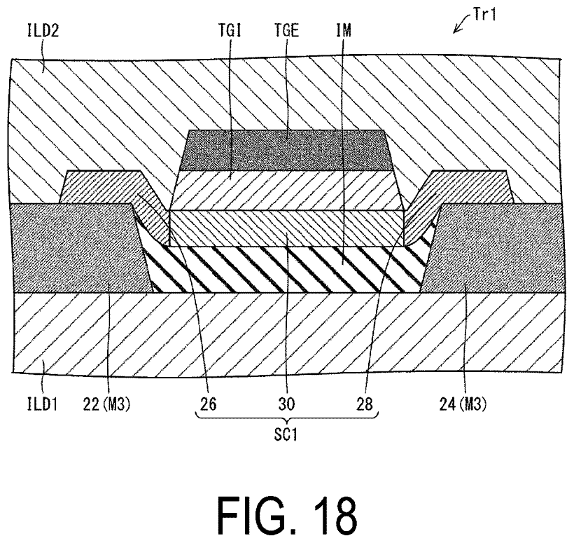

FIG. 18 is a schematic cross-sectional view illustrating a configuration example of the first transistor Tr1 according to the present embodiment. As illustrated in FIG. 18, the display device 2 according to the present embodiment is the same as the display device 2 according to the first embodiment described above, except that the distance from the upper surface of the insulating layer IM to the upper surface of the resin substrate 10 is not uniform.

When the liquid 20 including the application-type insulating material is applied, the upper surface of the liquid 20 including the application-type insulating material may become uneven due to surface tension. Further, when the liquid 20 including the application-type insulating material is solidified, the liquid 20 including the application-type insulating material or the insulating layer IM may expand and/or contract due to a temperature change and/or a change in state from a liquid to a solid, and the upper surface thereof may become uneven. In such a case, the distance from the upper surface of the insulating layer IM to the upper surface of the resin substrate 10 may become non-uniform.

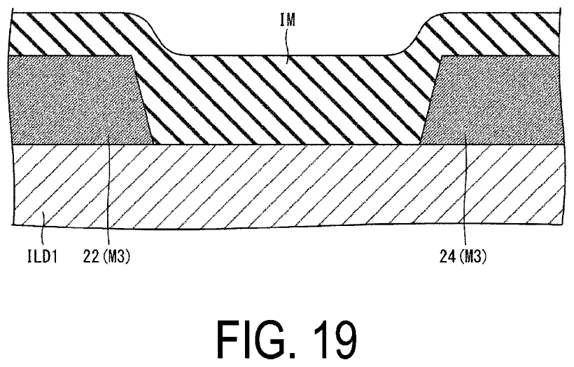

FIG. 19 is a schematic cross-sectional view illustrating an example of a step of forming the first transistor Tr1 illustrated in FIG. 18. Therefore, as illustrated in FIG. 19, after the liquid 20 including the application-type insulating material is solidified, the upper surface of the insulating layer IM may be formed in a valley shape in the gap between the first electrode 22 and the second electrode 24 of the first transistor Tl. Specifically, the distance from the upper surface of a portion, of the insulating layer IM, formed in the gap between the first electrode 22 and the second electrode 24 to the upper surface of the resin substrate 10 may be less than the distance from the upper surface of a portion, of the insulating layer IM, formed on the first electrode 22 and the second electrode 24 to the upper surface of the resin substrate 10. Of the portion formed in the gap, the entire upper surface may be inclined or curved, or only the upper surface of portions in the vicinity of the side surfaces of the first electrode 22 and the second electrode 24 may be inclined or curved.

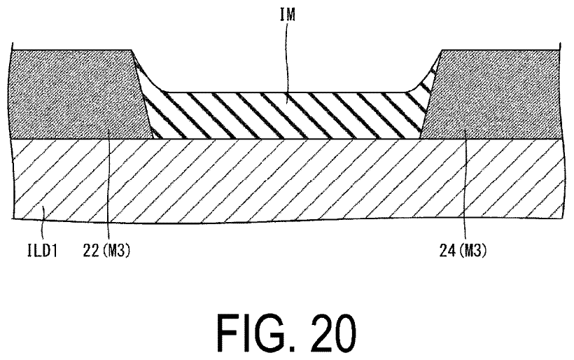

FIG. 20 is a schematic cross-sectional view illustrating an example of the step of forming the first transistor Tr1 illustrated in FIG. 18. As illustrated in FIG. 20, when the insulating layer IM is formed in the valley shape, even after etching the insulating layer IM, the upper surface of the insulating layer IM remains in the valley shape in the gap. Specifically, the distance from the upper surface of the insulating layer IM to the upper surface of the resin substrate 10 is formed such that the distance is less at an intermediate position between the first electrode 22 and the second electrode 24 than the distance at the edges at which the upper surface of the insulating layer IM is in contact with the first electrode 22 and the second electrode 24.

Therefore, in the insulating layer IM according to the present embodiment, the upper surface of the insulating layer IM may have the valley shape in the gap between the first electrode 22 and the second electrode 24, in a cross-sectional view of the display device 2. The configuration is not limited to this example, and the upper surface of the insulating layer IM may have another shape such as a mountain shape or a wave shape in the gap.

The present invention is not limited to each of the embodiments described above, and various modifications may be made within the scope of the claims. Embodiments obtained by appropriately combining technical approaches disclosed in each of the different embodiments also fall within the technical scope of the present invention. Furthermore, novel technical features can be formed by combining the technical approaches disclosed in each of the embodiments.

### REFERENCE SIGNS LIST

2 Display device
10 Resin substrate (substrate)
22 First electrode
24 Second electrode
26 First low-resistance portion
28 Second low-resistance portion
30 Channel portion
GE Gate electrode (second gate electrode)
ILD1 First interlayer insulating film (inorganic insulating film)
IM Insulating layer
PC Pixel circuit
SC1 Oxide semiconductor layer
SC2 Silicon-based semiconductor layer
TGI Gate insulating film
TGE Gate electrode (first gate electrode)
Tr1 First transistor
Tr2 Second transistor

1. A display device including a substrate and a first transistor located above the substrate, the display device comprising:
a first electrode and a second electrode located above the substrate and spaced apart from each other in a direction orthogonal to a normal direction of the substrate;
an insulating layer located in a gap between the first electrode and the second electrode and including an application-type insulating material; and
an oxide semiconductor layer, at least a portion of the oxide semiconductor layer configured to function as a channel of the first transistor, and the oxide semiconductor layer being in contact with an upper surface of the insulating layer.

2. The display device according to claim 1,
wherein the oxide semiconductor layer includes a channel portion configured to function as the channel, and first and second low-resistance portions having an electrical resistance value less than an electrical resistance value of the channel portion, and
the first low-resistance portion is in contact with an upper surface of the first electrode, and the second low-resistance portion is in contact with an upper surface of the second electrode.

3. The display device according to claim 2,
wherein the first low-resistance portion is in contact with a side surface of the first electrode, and the second low-resistance portion is in contact with a side surface of the second electrode.

4. The display device according to claim 1,
wherein the insulating layer is in contact with the side surfaces of the first electrode and the second electrode.

5. The display device according to claim 1,
wherein a distance from the upper surface of the insulating layer to an upper surface of the substrate is less than a distance from an upper surface of the first electrode and of the second electrode to the upper surface of the substrate.

6. The display device according to claim 1,
wherein a distance from the upper surface of the insulating layer to an upper surface of the substrate is identical to a distance from an upper surface of the first electrode and an upper surface of the second electrode to the upper surface of the substrate.

7. The display device according to claim 1,
wherein an upper surface of the insulating layer has a valley shape.

8. The display device according to claim 1,
wherein the insulating layer includes at least one of a spin-on glass material, an oxide including an alkaline earth metal, or an oxide including a lanthanoid.

9. The display device according to claim 1,
wherein the first transistor includes a gate insulating film located on the oxide semiconductor layer, and a first gate electrode located on the gate insulating film.

10. The display device according to claim 1,
wherein each of the first electrode and the second electrode is surrounded by the insulating layer.

11. The display device according to claim 1,
wherein an inorganic insulating film is provided below the insulating layer.

12. The display device according to claim 11, further comprising:
a second transistor including a silicon-based semiconductor layer and a second gate electrode located above the silicon-based semiconductor layer,
wherein the second gate electrode is covered with the inorganic insulating film.

13. A manufacturing method for a display device, the manufacturing method comprising:
forming, above a substrate, a first electrode and a second electrode spaced apart from each other in a direction orthogonal to a normal direction of the substrate;
forming an insulating layer located in a gap between the first electrode and second electrode and including an application-type insulating material; and
forming an oxide semiconductor layer, at least a portion of the oxide semiconductor layer being configured to function as a channel of the first transistor, and the oxide semiconductor layer being in contact with an upper surface of the insulating layer.

14. The manufacturing method for the display device according to claim 13,
wherein a coating film is formed by applying a liquid including the application-type insulating material on the first electrode, on the second electrode, and in the gap.

15. The manufacturing method for the display device according to claim 14,
wherein the insulating layer is formed by baking the coating film and etching the baked coating film in such a manner as to expose an upper surface of the first electrode and an upper surface of the second electrode.
